(19) United States
(12) Patent Application Publication
(10) Pub. No.: US 2025/0212606 A1
(43) Pub. Date: Jun. 26, 2025

(54) DISPLAY APPARATUS FOR PREVENTING LATERAL LEAKAGE CURRENT

(71) Applicant: LG Display Co., Ltd., Seoul (KR)

(72) Inventors: Hye-Ju CHOI, Paju-si (KR); Dae-Hee KIM, Paju-si (KR)

(21) Appl. No.: 18/979,287

(22) Filed: Dec. 12, 2024

(30) Foreign Application Priority Data
Dec. 22, 2023 (KR) 10-2023-0189647

(51) Int. Cl. H10K 59/121; H10K 59/12; H10K 59/122; H10K 59/38; H10K 59/80

(52) U.S. Cl. CPC H10K 59/1213; H10K 59/1201; H10K 59/122; H10K 59/38; H10K 59/873

(57) ABSTRACT

A display apparatus according to the present disclosure comprising a substrate including a plurality of sub-pixels, a transistor disposed in each sub-pixel, a bank layer surrounding plurality of sub-pixels, a first pattern and a second pattern disposed on the bank layer, and a light emitting device including a first electrode disposed in the sub-pixel between the bank layer, an organic layer on the first electrode, and a second electrode on the organic layer. The second electrode is extended from the upper surface of the organic layer to the upper surface of the first pattern and the side surfaces of the first and second patterns.

### CROSS-REFERENCE TO RELATED APPLICATIONS

This application claims priority to Korean Patent Application No. 10-2023-0189647, filed on Dec. 22, 2023, the entire contents of which is hereby expressly incorporated by reference into the present application.

### BACKGROUND

### Technical Field

The present disclosure relates to a display apparatus capable of preventing lateral leakage current.

### Description of the Related Art

As information technology develops, various types of small and thin display apparatus such as a Liquid Crystal Display Device, an Organic Light Emitting Display Device, a Plasma Display Device, a Micro LED Display Device, etc., are proposed. These display apparatuses are applied to various electronic devices such as smart phones and tablet PCs.

Inside the display apparatus, a display element including an organic light emitting layer and various electrodes are formed. In this display apparatus, there was a problem that if moisture from the outside penetrated into the display, the electrodes would corrode or the organic light emitting layer would deteriorate.

### BRIEF SUMMARY

In the manufacture of high-resolution display apparatuses, it is advantageous to reduce the distance between sub-pixels. However, the inventors of the present disclosure have recognized that as the distance between adjacent sub-pixels decreases, lateral leakage current generated between adjacent sub-pixels, and this lateral leakage current causes unwanted light emission from pixels. This lateral leakage current causes unwanted light emission from pixels, which becomes a major cause of display apparatus defects.

Various embodiments of the present disclosure address one or more issues in the related art, including the previously mentioned technical problem.

Various embodiments of the present disclosure provide a display apparatus capable of preventing lateral leakage current between adjacent sub-pixels by forming an organic layer in each sub-pixel and disconnect the organic layer between adjacent sub-pixels.

A display apparatus according to one embodiment of the present disclosure includes: a substrate including a plurality of sub-pixels, a transistor disposed in each sub-pixel, a bank layer surrounding plurality of sub-pixels, a first pattern and a second pattern disposed on the bank layer, and a light emitting device including a first electrode disposed in the sub-pixel between the bank layer, an organic layer on the first electrode, and a second electrode on the organic layer, and wherein the second electrode is extended from the upper surface of the organic layer to the upper surface of the first pattern and the side surfaces of the first and second patterns.

A width of the first pattern may be smaller than that of the second pattern to form an undercut shape, and the first pattern may be formed of a material having orthogonality and the second pattern may be formed of a photoresist. In particular, the first pattern may be formed of a fluoropolymer material containing a large amount of fluorine (F) in the functional while carbon-carbon bonds are formed continuously in a chain structure.

The second electrode may be integrally formed in entire sub-pixels.

The light emitting device further includes a third electrode on the organic layer between the second electrode and the third electrode may be formed of a half-transparent material or a metal.

An organic pattern and a conductive pattern are disposed on the second pattern. The organic pattern may be disconnected from the organic layer by the undercut shape of the first pattern and the second pattern and the conductive pattern may be disconnected from the third electrode by the undercut shape of the first pattern and the second pattern.

An auxiliary electrode is disposed between the first pattern and the second pattern, and connected electrically to the second electrode. The auxiliary electrode may be formed of the metal.

An encapsulation layer is disposed over the light emitting device and a color filter layer is disposed over the encapsulation layer.

A method of fabricating display apparatus according to the present disclosure comprising providing a substrate including a plurality of sub-pixels, forming transistor in each of the plurality of sub-pixels, forming a first electrode in each of the plurality of sub-pixels, forming a bank layer surrounding the sub-pixel, depositing an orthogonal material and a photoresist in entire area of the substrate, developing the photoresist to form a first pattern, over-etching the orthogonal material using the first pattern as a mask to form a second patter, the first pattern and the second pattern being formed in a undercut shape, depositing an organic material over the substrate using the first pattern and the second pattern of the undercut shape as a mask to form an organic layer in each of the sub-pixels and an organic pattern on the second pattern, heat-treating the first pattern and the second pattern, and forming a second electrode in the entire area of the substrate.

### BRIEF DESCRIPTION OF THE SEVERAL VIEWS OF THE DRAWINGS

FIG. 1 is a schematic block diagram of an organic light emitting display apparatus according to the present disclosure.

FIG. 2 is the schematic block diagram of a sub-pixel of the organic light emitting display apparatus according to the present disclosure.

FIG. 3 is a circuit diagram conceptually showing the sub-pixel of the organic light emitting display apparatus according to the present disclosure.

FIG. 4 is a plan view schematically showing a sub-pixel of the display apparatus according to the present specification.

FIG. 5 is a cross-sectional view of the display apparatus according to a first embodiment of the present disclosure.

FIGS. 6A to 61 are views showing a method of manufacturing the display apparatus according to a first embodiment of the present disclosure.

FIGS. 7A and 7B are enlarged cross-sectional views of area A of FIG. 6F and area B of FIG. 6H, respectively.

FIG. 8 is a cross-sectional view of the display apparatus according to a second embodiment of the present disclosure.

FIG. 9 is a cross-sectional view of the display apparatus according to a third embodiment of the present disclosure.

FIG. 10 is an enlarged cross-sectional view of area C of FIG. 9.

FIGS. 11A to 11E are views showing a method of manufacturing the display apparatus according to a third embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, dimensions (e.g., length, width, height, thickness, radius, diameter, area, etc.), ratios, angles, numbers, and the like disclosed in the drawings for describing the embodiments of the present disclosure are illustrative, and thus the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

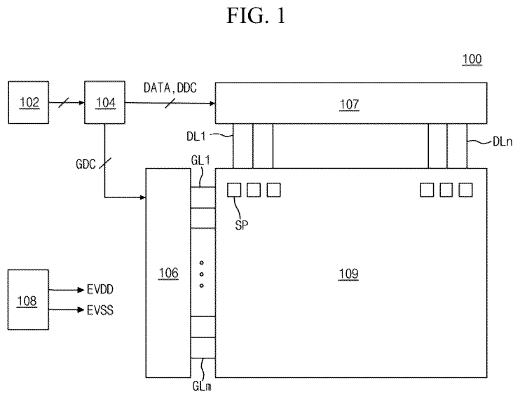

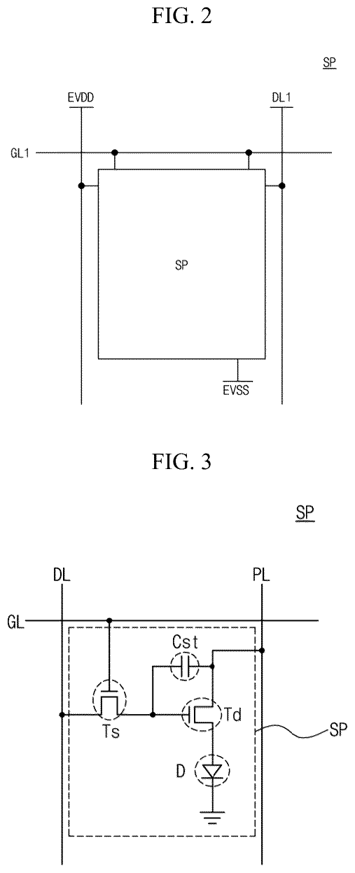

FIG. 1 is the schematic block diagram of a display apparatus 100 according to the present disclosure and FIG. 2 is the schematic block diagram of the sub-pixel SP shown in FIG. 1.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driver 106 includes various gate driving circuits, and the gate driving circuits may be directly formed on the substrate 110. In this case, the gate driver 106 may be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gatedriving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (it is called 2T1C), but is not limited thereto. The sub-pixel SP may be composed of 3T1C, 4T1C, 5T1C, 6T1C, 7T1C, 3T2C, 4T2C, 5T2C, 6T2C, 7T2, 8T2C, etc.

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor Td, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

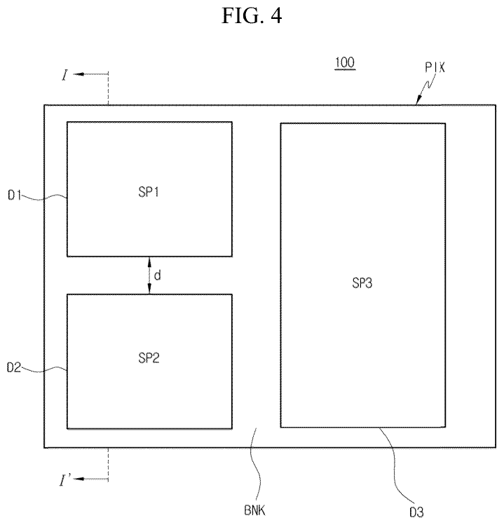

FIG. 4 is a drawing showing the pixel PIX of the display apparatus 100 according to the present disclosure.

Th display apparatus 100 according to the present disclosure includes a plurality of pixels PIX and each pixel PIX may include a plurality of sub-pixels SP1, SP2, and SP3. For example, the first sub-pixel SP1 may be a green sub-pixel that emits green light, the second sub-pixel SP2 may be a red sub-pixel that emits red light, and the third sub-pixel SP3 may be a blue sub-pixel that emits blue light. However, it is not limited thereto. The first sub-pixel SP1 may be the red sub-pixel or the blue sub-pixel, the second sub-pixel SP2 may be the green sub-pixel or the blue sub-pixel, and the third sub-pixel SP3 may be the green sub-pixel or the red sub-pixel. Further, the pixel PIX may include a white sub-pixel that emits white light

Although the sub-pixels SP1, SP2, and SP3 may be formed in an S-stripe shape in which the third sub-pixel SP3 is arranged vertically and the first sub-pixel SP1 and the second sub-pixel P2 are arranged horizontally, the sub-pixels SP1, SP2, and SP3 may also be formed in a stripe shape, a delta shape, or a diamond shape.

In the drawing, the size of the first sub-pixel SP1 is the smallest, the size of the second sub-pixel SP2 is in the middle, and the size of the third sub-pixel SP3 is the largest. However, the sizes the first to third sub-pixels SP1, SP2, and SP3 may all be the same. In addition, the size of the first sub-pixel SP1 may be the largest and the size of the third sub-pixel SP3 may be the smallest. In this way, in the present disclosure, the first to third sub-pixels SP1, SP2, and SP3 may be formed with various sizes as needed.

A bank layer BNK is formed around the sub-pixels SP1, SP2, and SP3. The bank layer BNK is arranged to surround each of the sub-pixels SP1, SP2, and SP3 to partition the sub-pixels SP1, SP2, and SP3. In other words, it can be said that a number of openings exposed to the outside are formed in the bank layer BNK, and the sub-pixels SP1, SP2, and SP3 are defined in each opening.

The bank layer BNK may be formed of a single layer, but may also be formed of multiple layers. For example, the bank layer BNK may be formed of two layer of a hydrophilic lower bank layer and a hydrophobic upper bank layer thereon. In this case, the width of the lower bank layer is wider than that of the upper bank layer, so that the lower bank layer and the upper bank layer are formed in a step structure, but is not limited thereto.

A light emitting device D1, D2, and D3 may be arranged in each of the sub-pixels SP1, SP2, and SP3. For example, the light emitting device D1, D2, and D3 may be white light emitting device that output the white light.

Although not shown in the drawing, each of the light emitting devices D1, D2, and D3 may include a first electrode, a second electrode, and an organic layer disposed therebetween. The first electrode may be an anode electrode. The first electrode is disposed in each of the sub-pixels SP1, SP2, and SP3 and is electrically disconnected from the first electrodes of the adjacent sub-pixels. A data voltage may be applied to the first electrode from an external data driving unit.

The organic layer is formed in the sub-pixels SP1, SP2, and SP3 and can be separated from the organic layers of adjacent sub-pixels. That is, the organic layer is formed in the first to third sub-pixels SP1, SP2, and SP3, but these organic layers are disconnected at the boundaries of the first to third sub-pixels SP1, SP2, and SP3.

The second electrode may be a cathode electrode. The second electrode may be integrally formed in the entire area of the display apparatus 100. A low voltage VSS may be supplied to the second electrode from an external power supply.

In the present disclosure, the gap d between adjacent sub-pixels SP1, SP2, and SP3 can be minimized to realize high resolution and improve the aperture ratio of the sub-pixels SP1, SP2, and SP3. To this end, the present disclosure reduces the gap d between the sub-pixels SP1, SP2, and SP3 while blocking the current flow path between the adjacent sub-pixels SP1, SP2, and SP3 to minimize the lateral leakage current in the adjacent sub-pixels SP1, SP2, and SP3 caused by the reduction in the gap d.

In particular, in the present disclosure, the organic layer, which is the flow path of the lateral current, is formed only in the sub-pixels SP1, SP2, and SP3, and the organic layer is disconnected between adjacent sub-pixels SP1, SP2, and SP3. Therefore, the lateral leakage current to the adjacent sub-pixels can be blocked, In the present disclosure, the organic layer is formed in the entire area of the sub-pixels SP1, SP2, and SP3 in a single process, but is disconnected between the sub-pixels SP1, SP2, and SP3, thereby simplifying the process of the organic layer and simultaneously blocking the inflow of lateral current.

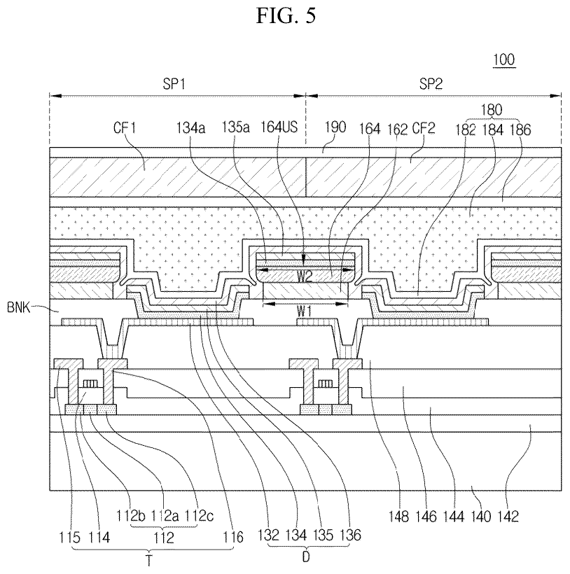

FIG. 5 is a cross-sectional view showing the structure of a sub-pixel of the display apparatus 100 according to the first embodiment of the present disclosure. In fact, the display apparatus 100 according to the first embodiment of the present disclosure includes first to third sub-pixels SP1, SP2, and SP3 that display different colors, but since the first to third sub-pixels SP1, SP2, and SP3 have substantially the same structure, only two adjacent sub-pixels SP1 and SP2 are illustrated in the drawing for convenience of explanation.

As shown in FIG. 5, a buffer layer 142 is formed on a substrate 140. The substrate 140 may be made of a hard material such as a glass or a plastic material, but not limited thereto. For example, the plastic material may include a polyimide, a polymethylmethacrylate, a polyethylene terephthalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in each sub-pixel SP1, and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at both sides of the channel region 112a.

The gate insulating layer 144 may be formed in the entire area of the substrate 140 or formed only in a part area of the substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor is disposed. The planarization layer 148 may be formed of the organic material such as photo acryl. but it is not limited thereto. The planarization layer 148 may include a plurality of layers including the inorganic layer and the organic layer.

A light emitting device D is disposed in each sub-pixel SP1 and SP2 on the planarization layer 148. The light emitting device D includes a first electrode 132, an organic layer 134, and a second electrode 136.

The first electrode 132 is disposed on the planarization layer 148 and electrically connected to the drain electrode 116 of the thin film transistor through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BNK is formed at the boundary between the sub-pixels SP1 and SP2 on the planarization layer 148. The bank layer 152 may be a barrier wall to define sub-pixels SP1 and SP2. The bank layer BNK divides each sub-pixel to prevent light of a specific color output from adjacent pixels from being mixed and output.

The bank layer BNK is formed to surround the sub-pixels SP1 and SP2 (see FIG. 4), and an opening area OPEN in which the first electrode 132 is exposed to the outside can be formed between the sub-pixels SP1 and SP2.

The bank layer BNK is made of at least one material of the inorganic insulating material such as SiNx or SiOx, the organic insulating material such as Benzo Cyclo Butene, acrylic resin, epoxy resin, phenolic resin, polyamide resin, or the photosensitizer including black pigment, but is not limited thereto.

A first pattern 162 and a second pattern 164 are formed on the bank layer BNK. The first pattern 162 may be formed of a material having orthogonality, and the second pattern 164 may be formed of a photoresist.

The orthogonality means that different configurations formed inside the display apparatus 100 have different properties. For example, since a specific layer inside the display apparatus 100 has completely different properties from other layers, the materials with orthogonality have little effect on other materials.

Further, the orthogonality can be understood as a characteristic in which two objects exist independently, regardless of each other. For example, the material having orthogonality can be both hydrophobicity which has a low affinity for water and oleophobicity which has a low affinity for oil.

Since the first pattern 162 has orthogonality, the chemical is not generated between the first pattern 162 and other layers, and the physical damage is not generated to other layers when the first pattern 162 is patterned. In the present disclosure, as the orthogonal material, a fluoropolymer material containing a large amount of fluorine (F) in the functional while carbon-carbon bonds are formed continuously in a chain structure can be used, but is limited thereto.

Since the width of the first pattern 162 is smaller than that of the second pattern 164, an undercut structure having a reverse step is formed at the boundary between the first pattern 162 and the second pattern 164. For example, in FIG. 5, the first pattern 162 has a first width W1 in a first direction and the second pattern 164 has a second width W2 in the same first direction. As illustrated, the second width W2 of the second pattern 164 is greater than the first width W1 of the first pattern 162 to form an undercut structure.

The organic layer 134 is formed on the upper surface of the first electrode 132 that is exposed to the outside through the opening area OPEN of the bank layer BNK. Further, an organic pattern 134a is formed on the upper surface 164US of the second pattern 164. As will be described in detail later, the organic layer 134 and the organic pattern 134a are formed integrally by the same process, but the organic layer 134 and the organic pattern 134a are disconnected by the undercut structure of the first pattern 162 and the second pattern 164.

In other words, although the organic material is deposited in the entire area of the substrate 140, since the organic layer 134 and the organic pattern 134a are disconnected from each other due to the undercut structure of the first pattern 162 and the second pattern 164, the organic layer 134 formed in each sub-pixel SP1 and SP2 is disconnected from the organic layer 134 of the adjacent sub-pixel SP1 and SP2. Accordingly, it is possible to block the lateral current from flowing to the adjacent sub-pixel SP1 and SP2 through the organic layer (134.

For example, the organic layer 134 may be the organic light emitting layer. Further, the organic layer 134 may be an inorganic light emitting layer, a nano-sized material layer, a quantum dot layer, a micro LED light emitting layer, or a mini LED light emitting layer, but is not limited thereto.

When the organic layer 134 is the organic light emitting layer, the organic layer 134 is formed of a blue organic light emitting layer and a yellow-fluorescent layer to emit the white light. Further, the organic layer 134 may be formed in a multi-stack structure. For example, when the organic layer 134 is formed in a triple stack structure, the first to third stacks may be arranged with two charge generation layers therebetween. Each of the first to third stacks may be formed of the organic light emitting layer, a hole injection layer, a hole transport layer, an electron transport layer, and an electron injection layer. For example, the organic light emitting layer of the first stack may emit red light, the organic light emitting layer of the second stack may emit blue light, and the organic light emitting layer of the third stack may emit green light.

A third electrode 135 is disposed on the organic layer 134, and a conductive pattern 135a is formed on the organic pattern 134a above the second pattern 164. The third electrode 135 and the conductive pattern 135a are made of the same material and are formed through a single process, but are disconnected due to the undercut structure of the first pattern 162 and the second pattern 164. When the display apparatus 100 is the top emission type, the third electrode 135 and the conductive pattern 135a may be made of the half-transparent conductive material that transmits light. For example, the third electrode 135 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the third electrode 135 may be the reflective electrode made of the opaque conductive material. For example, the third electrode 135 may be made of at least one or more of silver (Ag), aluminum (Al), gold (Au), molybdenum (Mo), tungsten (W), chromium (Cr), or alloys thereof.

A second electrode 136 is disposed on the third electrode 135. At this time, the second electrode 136 is formed integrally in the entire area of the display apparatus 100. That is, the second electrode 136 extends from the upper surface of the third electrode 135 of the sub-pixel SP1 and SP2 to the upper surface of the conductive pattern through the bank layer BNK, the first pattern 162, the second pattern 164, the organic pattern 134a, and the side surface of the conductive pattern 135a.

The second electrode 136 may be formed of a transparent metal oxide such as indium tin oxide ITO or indium zinc oxide IZO, but is not limited thereto.

The third electrode 135 and the conductive pattern 135a are disconnected from each other by the undercut structure of the first pattern 162 and the second pattern 164, but the second electrode 136 is not disconnected by the undercut structure of the first pattern 162 and the second pattern 164. This is because the degree of reverse step difference of the undercut structure of the first pattern 162 and the second pattern 164 when forming the third electrode 135 and the conductive pattern 135a is different from that of when forming the second electrode 136.

When the third electrode 135 and the conductive pattern 135a are formed, the degree of the reverse step between the first pattern 162 and the second pattern 164 is relatively large, so that the third electrode 135 and the conductive pattern 135a are disconnected from each other. On the other hand, when forming the second electrode 136, the degree of the reverse step between the first pattern 162 and the second pattern 164 is relatively small, so that the second electrode 136 is not disconnected at the boundary between the sub-pixels SP1 and SP2. This will be described in detail later.

The third electrode 135 and the second electrode 136 form the cathode electrode. Since the cathode electrode includes the third electrode 135 made of the metal and the second electrode 136 made of the metal oxide, the following effects can be obtained.

The third electrode 135 made of the metal has relatively high electrical conductivity compared to the second electrode 136 made of the metal oxide. Therefore, the image signal is applied to the entire area of the display apparatus 100 without signal delay to the organic light emitting device D through the third electrode 135 disposed in the sub-pixels SP1 and SP2.

Further, since the third electrodes 135 disposed in the sub-pixels SP1 and SP2 is electrically connected for each other by the second electrode 136, the cathode electrode is integrally formed over the entire display apparatus 100, and therefore the image signal can be applied to the entire area of the display apparatus 100.

An encapsulation layer 180 is formed over the second electrode 136 of the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 180 blocks impurities such as the oxygen and the moisture from the outside to prevent defects of the light emitting device D and various electrodes.

The encapsulation layer 180 may be formed of a first encapsulation layers 182a, 182b, and 182c, a second encapsulation layer 184, and a third encapsulation layer 186, but is not limited thereto. The encapsulation layer 180 may be formed of two layers or four or more layers.

The first encapsulation layers 182 and the third encapsulation layer 186 may be made of the inorganic material such as SiOx or SiNx, but are not limited thereto. The second encapsulation layer 184 may be made of the organic insulating material such as acrylic resin, epoxy resin, polyimide, polyethylene, or silicon oxycarbon (SiOC), but is not limited thereto. Further, the third encapsulation layer 186 may be made of thin metal (Face Seal Metal), but is not limited thereto.

Color filter layers CF1 and CF2 are formed on the encapsulation layer 180. Each of the color filter layers CF1 and CF2 may include R, G, and B color filters formed in each sub-pixel SP1 and SP2. The color filter layers CF1 and CF2 transmit only light of a corresponding wavelength among the light emitted from the light emitting device D and absorb light of other wavelengths to display R, G, and B colors.

Although not shown in figure, the color filter layers CF1 and CF2 may include a W color filter layer that transmits white light. By forming the W color filter layer, the luminance of the display apparatus 100 can be improved.

As such, in the present disclosure, color can be realized by disposing the color filter layers CF1 and CF2 on the encapsulation layer 180. Further, the reflectivity of the external light can be greatly reduced by absorbing a portion of the external light incident into the inside of the display apparatus 100 from the outside and reabsorbing a portion of the external light reflected at inside of the display apparatus 100. Therefore, the visibility can be improved by reducing reflectivity without having a separate polarizing plate in the display apparatus 100.

When the display apparatus 110 is the bottom emission type display apparatus, the color filter layers CF1 and CF2 may be disposed below the light emitting device D. For example, the color filter layers CF1, CF2 may be formed on the interlayer insulating layer 146 or on the gate insulating layer 144.

A protective member 190 is disposed on the color filter layers CF1 and CF2 and is attached by an adhesive (not shown in the figure). The protective member 190 is for protecting the display apparatus 100 and may be formed of glass or a transparent film. As such a film, a transparent protective film such as a PS (Polystyrene) film, a PE (Polyethylene) film, a PEN (Polyethylene Naphthalate) film, or a PI (Polyimide) film can be used.

As described above, in the display apparatus 100 according to the present disclosure, the organic layer 134 that emits white light is formed in the entire area of the substrate 140, but the organic layer 134 is disconnected in the adjacent sub-pixels SP1 and SP2 due to the undercut structure of the first pattern 162 and the second pattern 164. Accordingly, since the organic layer 134 can be formed through a single process, the process can be simplified and the lateral leakage current to adjacent sub-pixels SP1 and SP2 can be prevented due to the disconnection of the organic layer 134.

In particular, in the present disclosure, the first pattern 162 is made of the material having orthogonality and the second pattern 164 is made of the photoresist, so that when the first pattern 162 and the second pattern 164 having the undercut structure are formed, physical damage is not applied to other layers, and thus defects due to damage to the thin film layer can be prevented.

Hereinafter, the manufacturing method of the display apparatus 100 according to the present disclosure will be described in detail.

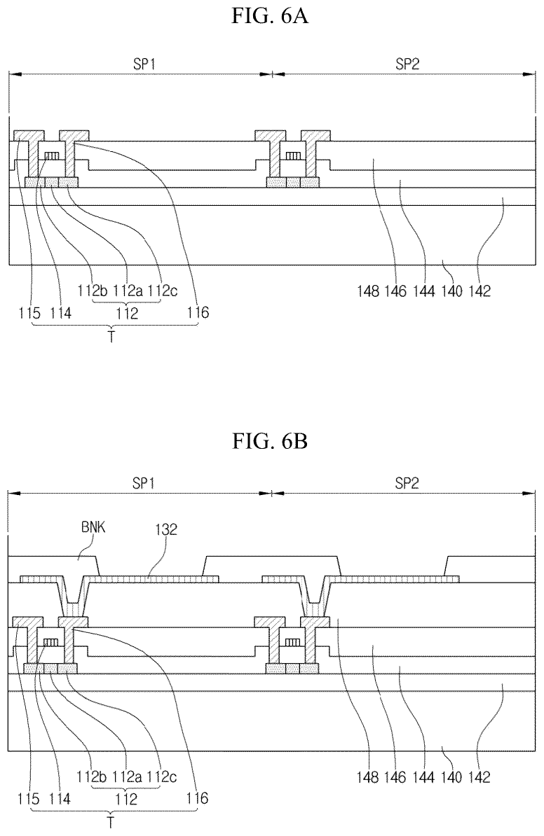

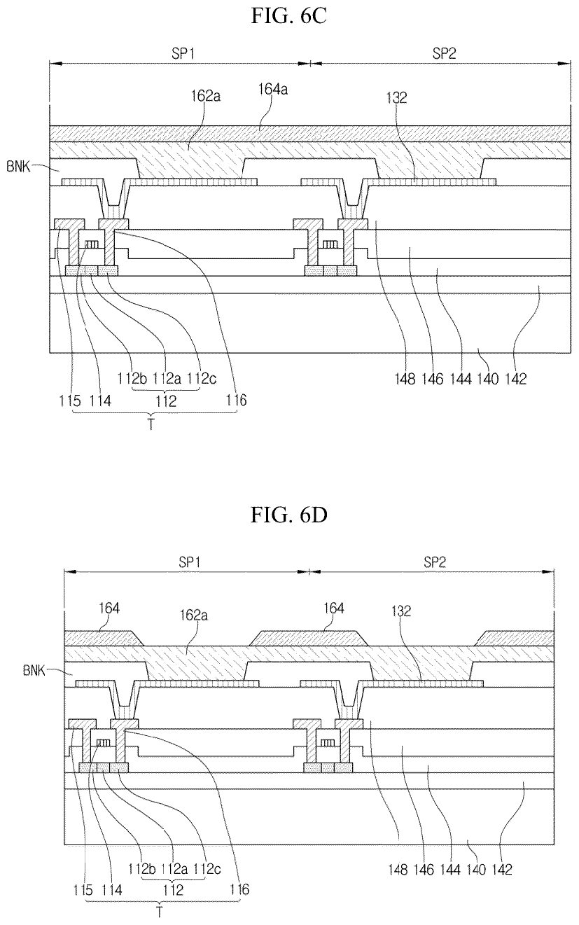

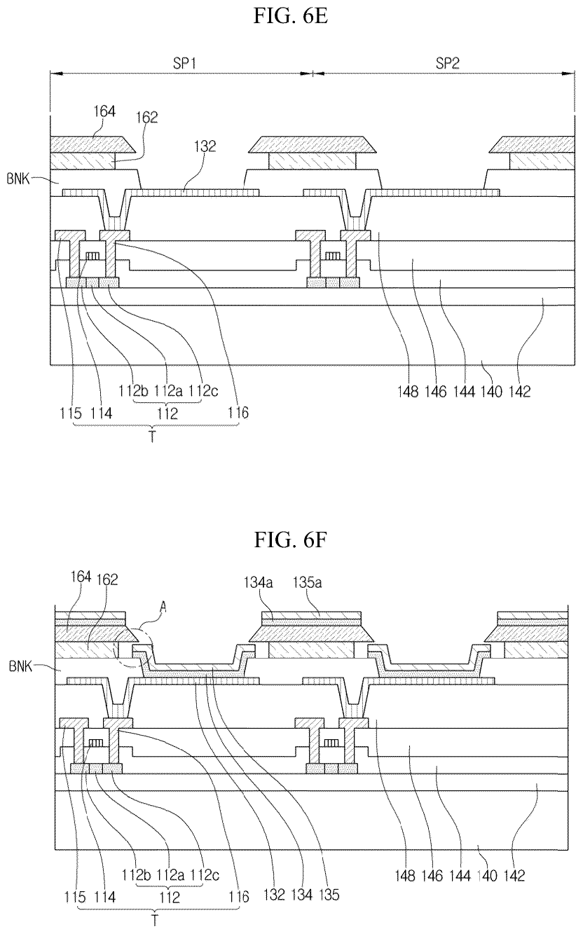

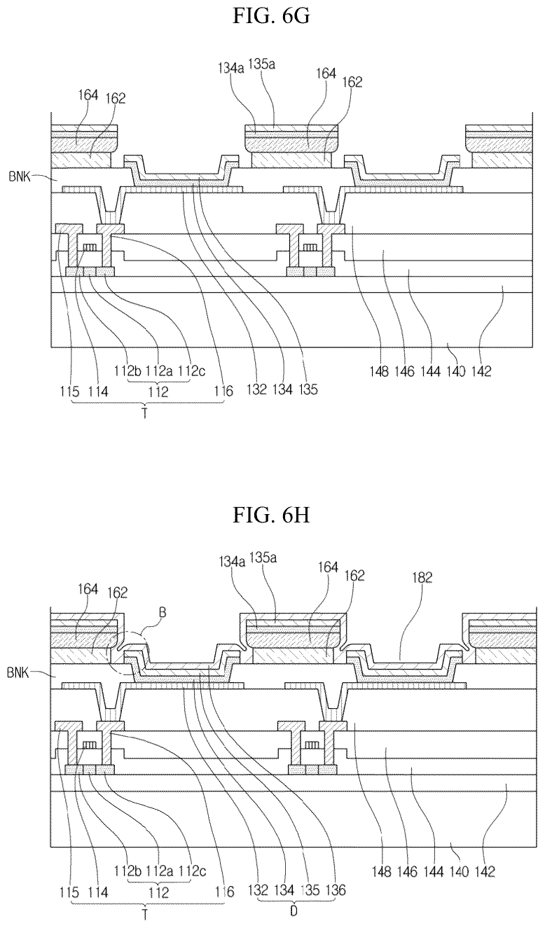

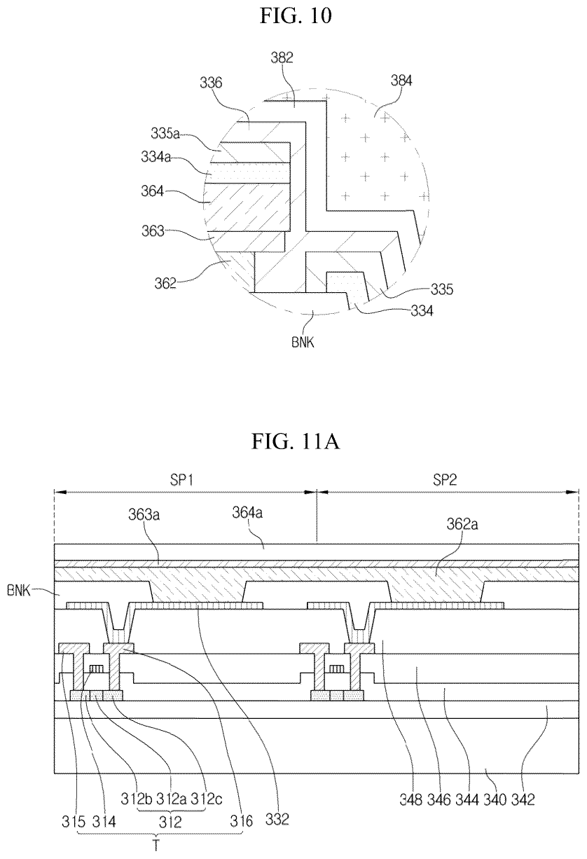

FIGS. 6A to 61 are views showing the method of manufacturing the display apparatus 100 according to the present disclosure.

First, as shown in FIG. 6A, the buffer layer 142 is formed over the entire substrate 140 including a plurality of sub-pixels SP1 and SP2.

The substrate 140 may be made of the hard material such as the glass or the plastic material such as the plastic material may include a polyimide, a polymethylmethacrylate, a polyethylene terephthalate, a Polyethersulfone, and a Polycarbonate.

The buffer layer 142 may be formed of the single layer of SiNx or SiOx, or multiple layers thereof.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer 112 in each of the first to third sub-pixels SP1, and SP2 on the buffer layer 142. Further, the impurities are doped into both sides of the semiconductor layer 112 to form the channel region 112a, the source region 112b, and the drain region 112c.

Subsequently, the gate insulating layer 144 is formed by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 114. Thereafter, the organic material such as photo acrylic material or the inorganic material such as SiNx or SiOx is deposited on the gate electrode 114 to form the interlayer insulating layer 146, and then the interlayer insulating layer 146 over the source region 112b and the drain region 112c of the semiconductor layer 112 is dry etched to form the contact holes therein.

Subsequently, the metal such as Cr, Mo, Ta, Cu, Ti, Al, or an Al alloy is deposited by the sputtering method and etched to form the source electrode 115 and the drain electrode 116 which are respectively ohmic-contacted to the source region 112b and the drain region 112c of the semiconductor layer 112 through the contact holes in each of the first to third sub-pixels SP1, SP2, and SP3.

Thereafter, as shown in FIG. 6B, the planarization layer 148 is formed by depositing the organic material such as photo-acryl on the source electrode 115 and the drain electrode 116, and then the planarization layer 148 on the drain electrode 116 is dry-etched to form the contact hole.

Subsequently, the metal or the metal oxide is deposited on the planarization layer 148 by a sputtering method and then etched by a wet etching method to form the first electrode 132 electrically connected to the drain electrode 116 through the contact hole in each of the sub-pixels SP1 and SP2. Thereafter, at least one material of the inorganic insulating material such as SiNx or SiOx, the organic material such as BCB (BenzoCycloButene), acrylic resin, epoxy resin, phenolic resin, polyamide resin, and polyimide resin, and the photoresist including the black pigment is deposited on an edge area of the planarization layer 148 and the first electrode 132 and dry-etched to form the bank layer BNK.

Subsequently, as shown FIG. 6C, the material having orthogonality, that is, the fluoropolymer material containing a large amount of fluorine (F) in the functional while carbon-carbon bonds are formed continuously in a chain structure and the photoresist are continuously deposited to form an orthogonal material layer 162a and a photoresist layer 164a in sub-pixels SP1 and SP2.

Thereafter, when the photoresist layer 164a is exposed and developed using a photomask (not shown), the second pattern 164 is formed on the orthogonal material layer 162a, as shown in FIG. 6D. In this case, the second pattern 164 may be formed with the width approximately similar to that of the bank layer BNK.

Subsequently, the second pattern 164 is used as a mask layer to etch the lower orthogonal material layer 162a, so that the first pattern 162 is formed under the second pattern 164, as shown in FIG. 6E. At this time, the first pattern 162 is over-etched to each a part of the first pattern 162 below the second pattern 164, so that the upper second pattern 164 and the lower first pattern 162 form the undercut shape.

Thereafter, the organic material is deposited in the entire area of the substrate 140, and then a half-transparent alloy such as LiF/Al, CsF/Al, Mg:Ag, Ca/Ag, Ca:Ag, LiF/Mg:Ag, LiF/Ca/Ag, LiF/Ca:Ag, or a metal such as silver (Ag), aluminum (Al), gold (Au), molybdenum (Mo), tungsten (W), or chromium (Cr) is deposited, so that the organic layer 134 and the third electrode 135 are formed on the first electrode 132 exposed between the bank layers BNK, and the organic pattern 134a and the conductive pattern 135a are formed on the second pattern 164.

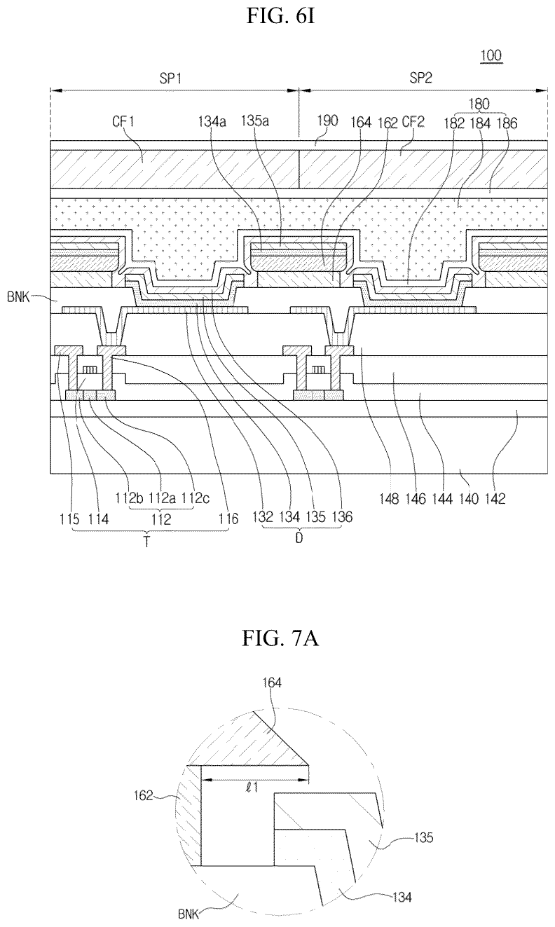

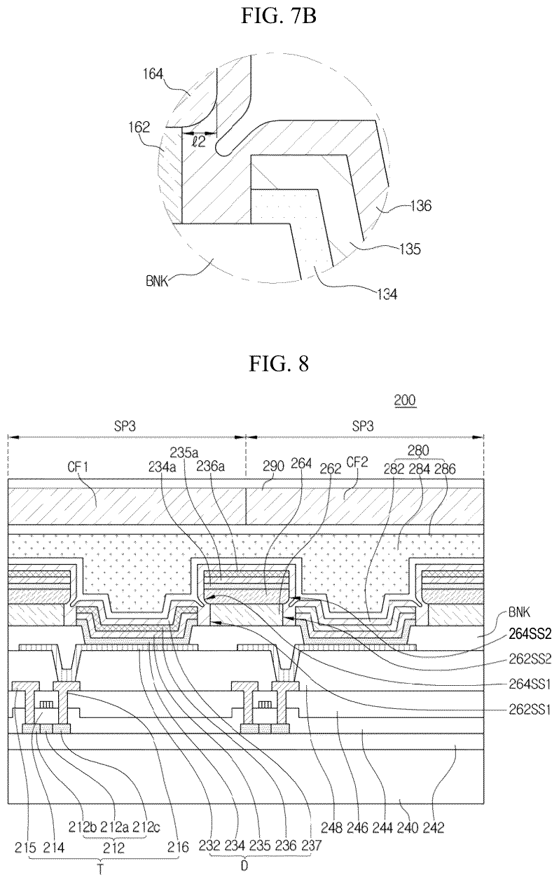

As shown in FIG. 7A, the width of the first pattern 162 is smaller that of the second pattern 164, so that the first pattern 162 and the second pattern 164 are formed in the undercut shape having the inverse step difference, At this time, the degree of reverse step difference between the first pattern 162 and the second pattern 164, i.e., the depth (l1) of the undercut shape, causes the disconnection of the organic layer 134 and the organic pattern 134a and the disconnection of the third electrode 135 and the conductive pattern 135a.

As described above, in the present disclosure, since the organic layer 134 is disconnected between adjacent sub-pixels SP1 and SP2, it is possible to prevent lateral leakage currents from flowing through the organic layer 134 to adjacent sub-pixels SP1 and SP2, thereby preventing defects caused by leakage currents.

Further, in the present disclosure, the organic layer 134 is formed at a desired location, i.e., on the first electrode 132 of the sub-pixels SP1 and SP2, by using the first pattern 162 having orthogonality. Since the orthogonal material has properties independent of other adjacent layers, when the first pattern 162 is formed, the chemical damage does not occur between the first pattern 162 and the lower layer, which is the planarization layer 148 or the first electrode 132, and when the first pattern 162 is etched, the damage is not caused to the planarization layer 148 or the first electrode 132.

Subsequently, the heat is applied to the entire area of the substrate 140 to perform heat treatment. The undercut shape of the first pattern 162 and the second pattern 164 can be changed by the heat treatment. As shown in FIG. 6G and FIG. 7B, the depth (l2) of the undercut shape is reduced by the heat treatment because of the reduction of the width difference between the first pattern 162 and the second pattern 164 (l2<l1), and thus the edge area of the second pattern 164 is transformed from an acute angle to a curved shape.

Thereafter, the metal or the metal oxide is deposited over the entire area of the substrate 140 to form a second electrode 136. At this time, since the undercut depth of the undercut shape of the first pattern 162 and the second pattern 164 is small and the edge area of the second pattern 164 is formed in the curved shape, the second electrode 136 is formed to extend from the upper surface of the conductive pattern 135a on the second pattern 164 along the side surfaces of the first pattern 162 and the second pattern 164 to the upper surface of the third electrode 135. That is, the second electrode 136 is formed integrally without the disconnection in the entire area of the sub-pixel SP1 and SP2.

Thereafter, as shown in FIG. 6I, the inorganic material is deposited in the entire area of the sub-pixels SP1 and SP3 to form the first encapsulation layer 182, and the organic material is deposited on the first encapsulation layer 182 to form the second encapsulation layer 184. Thereafter, the inorganic material is deposited on the second encapsulation layer 184 to form the third encapsulation layer 186, thereby forming the encapsulation layer 180 to seal the display apparatus 100.

Subsequently, the color resist and the like is deposited on the encapsulation layer 180 and patterned to form color filter layers CF1 and CF2 in the sub-pixels SP1 and SP2. At this time, the color filter layers CF1 and CF2 may be the red color filter layer, the green color filter layer, and the blue color filter layer. Further, the color filter layers CF1 and CF2 may be the white color filter layer. The W color filter layer may form a separate layer that directly transmits white light, or may directly transmit white light without the separate layer.

Thereafter, the transparent protective film 190 such as a PS (polystyrene) film, a PE (polyethylene) film, a PEN (polyethylene naphthalate) film, or a PI (polyimide) film is attached on the color filter layers CF1 and CF2 using an adhesive (not shown in the drawing) such as an OCR (optical clearance resin) or an OCA (optical clearance adhesive) to manufacture the display apparatus 100.

As described above, in the display apparatus 100 according to the present disclosure, the first pattern 162 having orthogonality and the second pattern 164 made of the photoresist are formed in the undercut shape so that the single organic layer 134 can be formed for each sub-pixels SP1 and SP2 through the single depositing process, thereby simplifying the manufacturing process.

At this time, since the first pattern 162 for patterning the organic layer 134 is composed of the material having orthogonality, no physical damage is inflicted on other layers when forming the first pattern 162 and the second pattern 164 having the undercut structure. Accordingly, it is possible to prevent defects due to damage to the thin film layer.

FIG. 8 is the cross-sectional view showing the structure of the display apparatus 200 according to the second embodiment of the present disclosure. At this time, the description of the same structure as the first embodiment of FIG. 5 will be omitted or simplified, and only the different structures will be described in detail.

As shown in FIG. 8, in the display apparatus 200 according to the second embodiment of the present disclosure, the thin film transistor T and the light emitting device D are disposed in each of the sub-pixels SP1 and SP2.

The thin film transistor T includes the semiconductor layer 212 disposed on the buffer layer 242, the gate electrode 214 disposed on the gate insulating layer 244, the source electrode 215 and the drain electrode 216 disposed on the interlayer insulating layer 246.

The light emitting device D is disposed in each of the sub-pixels SP1 and SP2 divided by the bank layer BNK. The light emitting device D includes the first electrode 232, the organic layer 234, the third electrode 235, the second electrode 236, and the fourth electrode 237. At this time, the first electrode 232 may be the anode electrode and the second to fourth electrodes 235, 236, and 237 may be the cathode electrode.

The first electrode 232 is disposed in each of the sub-pixels SP1 and SP2. The first electrode 232 may be formed of at least one of silver (Ag), aluminum (Al), gold (Au), molybdenum (Mo), tungsten (W), chromium (Cr), or an alloy thereof, and may also be formed of the transparent metal oxide layer such as indium tin oxide (ITO) or indium zinc oxide (IZO).

The third electrode 235 and the second electrode 236, which are cathode electrodes, are formed in the entire area of the display apparatus 200, but are disconnected at the boundary of the sub-pixels SP1 and SP2 by the first pattern 262 and the second pattern 364 in the undercut shape.

The first pattern 262 is made of the material having orthogonality, that is, the fluoropolymer material containing a large amount of fluorine (F) in the functional while carbon-carbon bonds are formed continuously in a chain structure and the second pattern 264 is made of the photoresist. At this time, the width of the first pattern 262 is formed smaller than that of the second pattern 264, so that the first pattern 262 and the second pattern 264 are formed in the undercut shape having the reverse step.

The third electrode 235 may be made of the half-transparent alloy such as LiF/Al, CsF/Al, Mg:Ag, Ca/Ag, Ca:Ag, LiF/Mg:Ag, LiF/Ca/Ag, LiF/Ca:Ag, or the metal such as silver (Ag), aluminum (Al), gold (Au), molybdenum (Mo), tungsten (W), or chromium (Cr). The second electrode 236 may be made of the transparent metal oxide that transmits light, such as ITO or IZO.

In this embodiment, the reason for forming the second electrode 236 made of the transparent metal oxide on the third electrode 235 is to prevent oxidation of the third electrode 235. The third electrode 235 is formed by sputtering over the entire area of the substrate 240 after forming the organic layer 234. At this time, since the third electrode 235 is exposed to the outside, the third electrode 235 is oxidized by combining with the oxidation in the air.

The oxidation of the third electrode 235 causes impurities such as oxygen to penetrate into the adjacent organic layer 234, and the organic layer 234 is deteriorated due to this impurity penetration, resulting in a defective display apparatus 200. The second electrode 236 made of the metal oxide is formed on the third electrode 235, so that the third electrode 235 is not exposed to the outside, thereby preventing oxidation of the third electrode 235.

The fourth electrode 237 is formed in the entire area of the display apparatus 200. That is, the fourth electrode 237 is formed to extend from the upper surface of the second electrode 236 of the sub-pixels SP1 and SP2 to the side surfaces 262SS1, 262SS2 of the first pattern 262, the side surfaces 264SS1, 264SS2 of the second pattern 264, the side surfaces of the organic pattern 234a, the first conductive pattern 235a, and the second conductive pattern 236a, which are disposed on the upper surface of the second pattern 264, and the upper surface of the second conductive pattern 236a.

The first pattern 262 and the second pattern 264 have the undercut shape, so that the third electrode 235 and the first conductive pattern 235a are disconnected from each other, and the second electrode 236 and the second conductive pattern 236a are disconnected from each other. On the other hand, since the fourth electrode 237 is formed in the entire area of the display apparatus 200, the cathode electrodes formed in each of the sub-pixels SP1 and SP2 is electrically connected for each other by the fourth electrode 237.

The encapsulation layer 280 is formed over organic light emitting device D, the color filters CF1 and CF2 are disposed thereon, and the protective member 290 is disposed on the color filter layers CF1 and CF2.

While the cathode electrode of the display apparatus 100 of the first embodiment is formed of the third electrode 135 made of the alloy or the metal and the second electrode 136 made of the metal oxide, the cathode electrode of the display apparatus 200 of this embodiment is formed the third electrode 235 made of the alloy or the metal, the second electrode 236 made of the metal oxide, and the fourth electrode 237 made of the metal oxide.

However, the cathode electrode of the present disclosure is not limited to this configuration. The cathode electrode of the present disclosure may be formed only of the second electrode made of the metal oxide. At this time, the second electrode is disposed on the organic layer, and can be formed in the entire area of the display apparatus without being disconnected by the undercut shape of the first pattern and the second pattern.

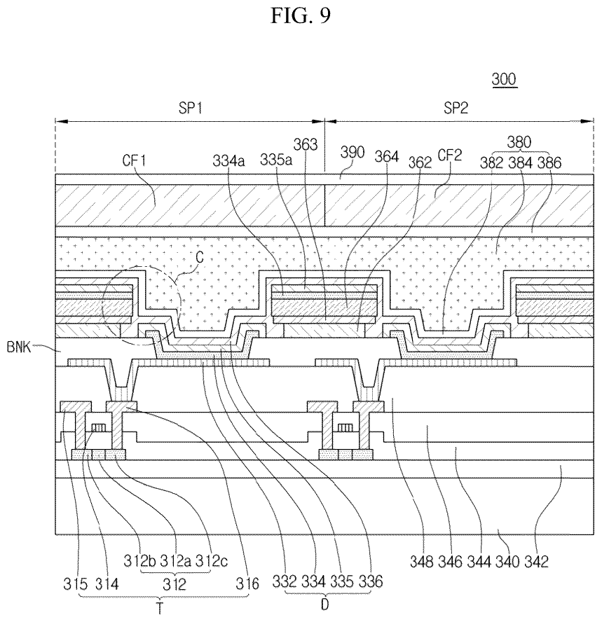

FIG. 9 is the cross-sectional view showing the structure of the display apparatus 300 according to the third embodiment of the present disclosure. At this time, the description of the same structure as the first embodiment of FIG. 5 will be omitted or simplified, and only the different structures will be described in detail.

As shown in FIG. 9, in the display apparatus 300 according to the third embodiment of the present disclosure, the thin film transistor T and the light emitting device D are disposed in each of the sub-pixels SP1 and SP2.

The thin film transistor T includes the semiconductor layer 312 disposed on the buffer layer 342, the gate electrode 314 disposed on the gate insulating layer 344, the source electrode 315 and the drain electrode 316 disposed on the interlayer insulating layer 346.

The light emitting device D is disposed in each of the sub-pixels SP1 and SP2 divided by the bank layer BNK. The light emitting device D includes the first electrode 332, the organic layer 334, the third electrode 335, and the second electrode 336. At this time, the first electrode 332 may be the anode electrode and the second and third electrodes 336 and 335 may be the cathode electrode.

The first electrode 332 is disposed in each of the sub-pixels SP1 and SP2. The first electrode 332 may be formed of at least one of silver (Ag), aluminum (Al), gold (Au), molybdenum (Mo), tungsten (W), chromium (Cr), or an alloy thereof, and may also be formed of the transparent metal oxide layer such as indium tin oxide (ITO) or indium zinc oxide (IZO).

The bank layer BNK is formed on the planarization layer 348 between the adjacent sub-pixels SP1 and SP2. The first pattern 362 is disposed on the bank layer BNK. The first pattern 362 may be made of the material having orthogonality, that is, the fluoropolymer material containing a large amount of fluorine (F) in the functional while carbon-carbon bonds are formed continuously in a chain structure.

An auxiliary electrode 363 is disposed on the first pattern 362. The auxiliary electrode 363 is formed in a matrix shape over the entire area of the substrate 340 similar to the bank layer BNK. The auxiliary electrode 363 may be made of at least one of silver (Ag), aluminum (Al), gold (Au), molybdenum (Mo), tungsten (W), chromium (Cr), or an alloy thereof.

The second pattern 364 is formed on the auxiliary electrode 363. The second pattern 364 is made of the photoresist. The width of the second pattern 364 and the width of the auxiliary electrode 363 are substantially the same, and the width of the first pattern 362 is smaller than the widths of the second pattern 364 and the auxiliary electrode 363, so that the first pattern 362 at the bottom and the auxiliary electrode 363 and the second pattern 364 at the top are formed in the undercut shape having the reverse step.

The organic layer 334 and the third electrode 335 are formed on the first electrode 332 between the bank layers BNK, and the organic pattern 334a and the conductive pattern 335a are formed on the second pattern 364. The organic layer 334, the organic pattern 334a, the third electrode 335, and the conductive pattern 335a are formed integrally over the entire area of the substrate 340, but are disconnected from each other at the boundary of the sub-pixels SP1 and SP2 by the undercut shape of the first pattern 362, the auxiliary electrode 363, and the second pattern 364.

The third electrode 335 may be made of the metal such as silver (Ag), aluminum (Al), gold (Au), molybdenum (Mo), tungsten (W), or chromium (Cr). The second electrode 336 may be made of the transparent metal oxide that transmits light such as ITO or IZO.

Further, although not shown in the drawing, the metal oxide layer may be formed on the third electrode 335 to prevent oxidation of the third electrode 335 during the process.

The second electrode 336 is formed in the entire area of the display apparatus 300. That is, the second electrode 336 is formed to extend continuously from the upper surface of the third electrode 335 of the sub-pixels SP1 and SP2 to the side surfaces of the first pattern 362, the auxiliary electrode 363, and the second pattern 364, the side surfaces of the organic pattern 334a and the conductive pattern 335a over the upper portion of the second pattern 364, and the upper surface of the conductive pattern 335a.

Due to the undercut shape of the first pattern 362, the auxiliary electrode 363, and the second pattern 364, the organic layer 334 and the organic pattern 334a are disconnected from each other, and the third electrode 335 and the conductive pattern 335a are disconnected from each other. On the other hand, since the second electrode 336 is formed in the entire area of the display apparatus 300, the cathode electrode formed in each of the sub-pixels SP1 and SP2 is electrically connected for each other by the second electrode 336.

Since the auxiliary electrode 363 made of the conductive metal having good conductivity is arranged in the matrix shape between the sub-pixels SP1 and SP2 in the entire area of the display apparatus 300, the auxiliary electrode 363 is electrically connected to the second electrode 336 having poor conductivity in the sub-pixels SP1 and SP2, so that the signal applied from the outside is applied to the second electrode 336 through the auxiliary electrode 363 without the signal delay. As a result, it is possible to prevent a defect due to the signal delay to the cathode electrode.

Although not shown in the drawing, in the display apparatus 300 of this embodiment, the second electrode 336 can be formed directly on the organic layer 334 without the third electrode 335. In this case, the second electrode 336 is electrically connected to the auxiliary electrode 363 to supply the signal to the entire area of the display apparatus 300, thereby preventing signal delay by the high resistance of the metal oxide of the second electrode 336.

Referring again to FIG. 9, the encapsulation layer 380 is formed on the organic light emitting device D, the color filters CF1 and CF2 are formed on the encapsulation layer 380, and the protective member 390 is disposed on the color filter layers CF1 and CF2.

As described above, in the display apparatus 300 of this embodiment, by arranging the auxiliary electrode 363 between the first pattern 362 and the second pattern 364 on the bank layer BNK to electrically connect the second electrode 336 to the auxiliary electrode 363, it is possible to prevent the defect due to the signal delay to the cathode electrode.

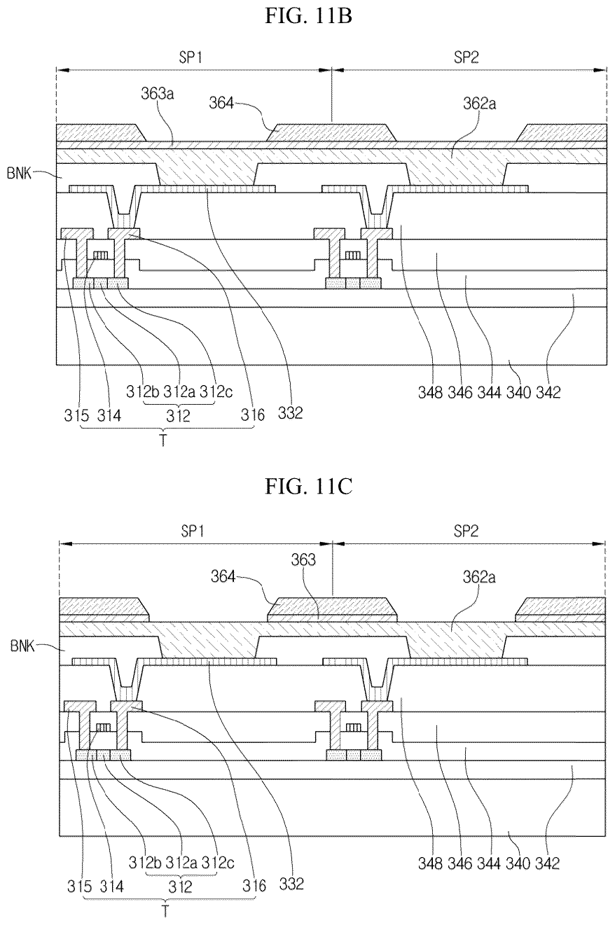

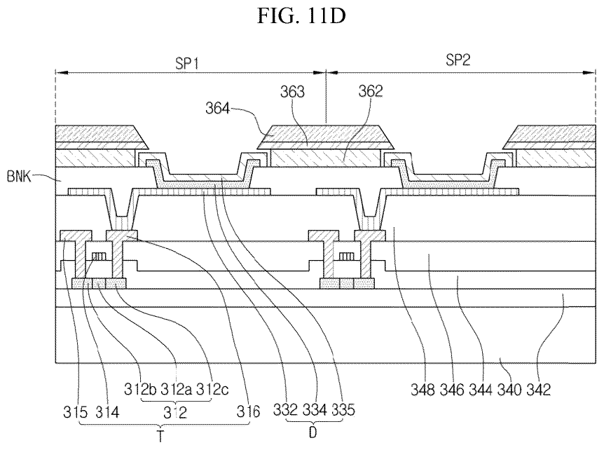

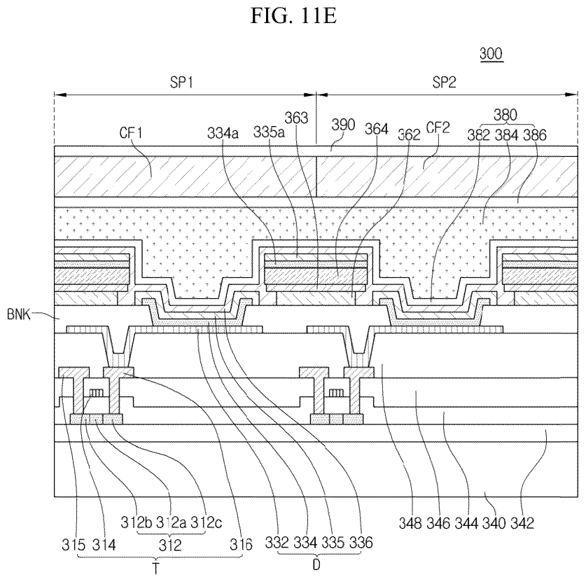

FIGS. 11A to 11E are drawings showing the method for manufacturing the display apparatus 300 according to the third embodiment of the present disclosure.

As shown in FIG. 11A, first, the thin film transistor T is formed in each of the sub-pixels SP1 and SP2 over the substrate 340, and then the planarization layer 348 is formed over the entire area of the substrate 340.

Thereafter, the planarization layer 348 on the drain electrode 316 is dry-etched to form the contact hole, and then the metal or the metal oxide is deposited on the planarization layer 348 by the sputtering method and etched by the wet-etching method to form the first electrode 332 that is electrically connected to the drain electrode 316 through the contact hole in each of the sub-pixels SP1 and SP2.

Subsequently, the bank layer BNK is formed on the edge area of the planarization layer 348 and the first electrode 332, and then the material layer 362a made of the fluoropolymer material containing a large amount of fluorine (F) in the functional while carbon-carbon bonds are formed continuously in a chain structure, the metal layer 363a made of the metal, and the photoresist layer 364a are formed.

Thereafter, as shown in FIG. 11B, the photoresist layer 364a is exposed and developed using the photomask (not shown in the drawing) to form the second pattern 364 on the metal layer 363a above the bank layer BNK. At this time, the second pattern 364 can be formed to have the width approximately similar to that of the bank layer BNK.

Thereafter, as shown in FIG. 11C, the metal layer 363a is etched using the second pattern 364 as the mask layer to form the auxiliary electrode 363. At this time, the auxiliary electrode 363 is formed to have substantially the same width as the second pattern 364.

Subsequently, as shown in FIG. 11D, the orthogonal material layer 362a is etched using the second pattern 364 as the mask layer to form the first pattern 362 under the auxiliary electrode 363. At this time, the first pattern 362 is over-etched, so that a part of the first pattern 362 under the auxiliary electrode 363 is etched, and the auxiliary electrode 363, the second pattern 364, and the first pattern 362 form the undercut shape.

Thereafter, the organic material and the metal oxide such as IZO or ITO are continuously over the entire area of the substrate 340 to form the organic layer 334 and the third electrode 335 on the first electrode exposed between the bank layers BNK and to form the organic pattern 334a and the conductive pattern 335a on the second pattern 364.

At this time, the organic layer 334 and the third electrode 335 are respectively disconnected from the organic pattern 334a and the conductive pattern 335a by the undercut shape of the first pattern 362, the auxiliary electrode 363, and the second pattern 364. That is, the organic light emitting material and the metal oxide are deposited over the entire area of the substrate 340, but he organic layer and the conductive layer are disconnected by the undercut shape of the first pattern 362, the auxiliary electrode 363, and the second pattern 364.

Thereafter, as shown in FIG. 11E, the heat is applied to the entire area of the substrate 340 to perform heat treatment. The undercut shape of the first pattern 362, the auxiliary electrode 363, and the second pattern 364 can be changed by the heat treatment. That is, the depth of the undercut shape is reduced by the heat treatment because of the reduction of the width difference between the first pattern 362 and the second pattern 364, and thus the edge areas of the auxiliary electrode 363 and the second pattern 364 is transformed from the acute angle to the curved shape.

Thereafter, the metal or the metal oxide is deposited over the entire area of the substrate 340 to form the second electrode 336. At this time, since the undercut depth of the undercut shape of the first pattern 362 and the second pattern 364 is small and the edge area of the second pattern 364 is formed in the curved shape, the second electrode 336 is formed to extend from the upper surface of the conductive pattern 335a on the second pattern 364 along the side surfaces of the first pattern 362, the auxiliary electrode 363, and the second pattern 364 to the upper surface of the third electrode 335. That is, the second electrode 336 is formed integrally without the disconnection in the entire area of the sub-pixel SP1 to be electrically connected to the side and bottom surfaces of the auxiliary electrode 363.

Thereafter, the inorganic material is deposited in the entire area of the sub-pixels SP1 and SP3 to form the first encapsulation layer 382, and the organic material is deposited on the first encapsulation layer 382 to form the second encapsulation layer 384. Thereafter, the inorganic material is deposited on the second encapsulation layer 384 to form the third encapsulation layer 386, thereby forming the encapsulation layer 380 to seal the display apparatus 300.

Subsequently, the color resist and the like is deposited on the encapsulation layer 380 and patterned to form the color filter layers CF1 and CF2 in the sub-pixels SP1 and SP2 and then the transparent protect film 382 is attached to the color filter layers CF1 and CF2 by the adhesive (not shown in the drawing).

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of sub-pixels;
a transistor disposed in each sub-pixel;
a bank layer surrounding plurality of sub-pixels;
a first pattern and a second pattern on the bank layer; and
a light emitting device including:
a first electrode disposed in the sub-pixel between the bank layer,
an organic layer on the first electrode, and
a second electrode on the organic layer, and
wherein the second electrode is extended from an upper surface of the organic layer to an upper surface of the first pattern and side surfaces of the first and second patterns.

2. The display apparatus of claim 1, wherein a width of the first pattern is smaller than that of the second pattern to form an undercut shape.

3. The display apparatus of claim 1, wherein the first pattern is formed of a material having orthogonality and the second pattern is formed of a photoresist.

4. The display apparatus of claim 3, wherein the first pattern is formed of a fluoropolymer material containing a large amount of fluorine (F) in the functional while carbon-carbon bonds are formed continuously in a chain structure.

5. The display apparatus of claim 1, wherein the second electrode is integrally formed in entire sub-pixels.

6. The display apparatus of claim 1, further comprising a third electrode on the organic layer between the second electrodes.

7. The display apparatus of claim 6, wherein the third electrode is formed of a half-transparent material.

8. The display apparatus of claim 6, wherein the third electrode is formed of a metal.

9. The display apparatus of claim 6, further comprising:
an organic pattern on the second pattern; and
a conductive pattern on the organic pattern.

10. The display apparatus of claim 9,
wherein the organic pattern is disconnected from the organic layer by the undercut shape of the first pattern and the second pattern, and
wherein the conductive pattern is disconnected from the third electrode by the undercut shape of the first pattern and the second pattern.

11. The display apparatus of claim 1, further comprising an auxiliary electrode disposed between the first pattern and the second pattern, and connected electrically to the second electrode.

12. The display apparatus of claim 11, wherein the auxiliary electrode is formed of the metal.

13. The display apparatus of claim 1, further comprising:
an encapsulation layer on the light emitting device; and
a color filter layer on the encapsulation layer.

14. A method of fabricating a display apparatus, the method comprising:
providing a substrate including a plurality of sub-pixels;
forming transistor in each of the plurality of sub-pixels;
forming a first electrode in each of the plurality of sub-pixels;
forming a bank layer surrounding the sub-pixel;
depositing an orthogonal material and a photoresist in entire area of the substrate;
developing the photoresist to form a first pattern;
over-etching the orthogonal material using the first pattern as a mask to form a second patter, the first pattern and the second pattern being formed in an undercut shape;
depositing an organic material over the substrate using the first pattern and the second pattern of the undercut shape as a mask to form an organic layer in each of the sub-pixels and an organic pattern on the second pattern;
heat-treating the first pattern and the second pattern; and
forming a second electrode in the entire area of the substrate.

15. The method of claim 1, further comprising:
depositing a conductive material over the substrate using the first pattern and the second pattern of the undercut layer as the mask layer to form a third electrode on the organic layer in each of the sub-pixels and a conductive pattern on the organic pattern.

16. The method of claim 15, wherein the organic layer and the organic pattern are disconnected from each other, and the third electrode and the conductive pattern are disconnected from each other by the first pattern and the second pattern of the undercut shape.

17. The method of claim 14, further comprising forming an auxiliary electrode connected electrically to the second electrode between the first pattern and the second pattern.
